(19) United States
(12) Patent Application Publication
(10) Pub. No.: US 2024/0136159 A1
(43) Pub. Date: Apr. 25, 2024

(54) Metallic Shield For Stable Tape-Frame Substrate Processing

(71) Applicant: Applied Materials, Inc., Santa Clara, CA (US)

(72) Inventors: Harish Varma PENMETHSA, Dublin, CA (US); Ying WANG, Singapore (SG); Xundong DAI, Singapore (SG); Alejandro LIZARRAGA MALDONADO, San Jose, CA (US); Chin Seng LAU, Singapore (SG)

(21) Appl. No.: 18/088,417

(22) Filed: Dec. 23, 2022

Related U.S. Application Data
(60) Provisional application No. 63/419,141, filed on Oct. 25, 2022.

(51) Int. Cl. H01J 37/32; H01L 21/683; H01L 21/687

(52) U.S. Cl. CPC H01J 37/32651; H01J 37/32568; H01J 37/32715; H01L 21/6836; H01L 21/68721; H01J 37/32082; H01J 2237/3343; H01L 2221/68327

(57) ABSTRACT

Embodiments of process kits for use in a substrate process chamber are provided herein. A process kit for a substrate process chamber including: a cover ring configured to extend over unprotected dicing tape of a tape frame substrate during use and having a central opening configured to expose a semiconductor wafer supported on the dicing tape during use; and a metallic shield disposed adjacent to at least a portion of a lower surface of the cover ring such that the metallic shield at least partially lines the lower surface.

### CROSS-REFERENCE TO RELATED APPLICATIONS

This application claims benefit of U.S. provisional patent application Ser. No. 63/419,141, filed Oct. 25, 2022, which is herein incorporated by reference in its entirety.

### FIELD

Embodiments of the present disclosure generally relate to substrate processing equipment.

### BACKGROUND

In semiconductor substrate processing, integrated circuits are formed on a substrate composed of silicon or other semiconductor material. In general, layers of various materials which are either semiconducting, conducting or insulating are utilized to form the integrated circuits. After integrated circuit devices have been formed upon a semiconductor substrate, such as a 300 mm silicon substrate, the individual devices are separated from the semiconductor substrate by a process known as singulation or “dicing” where substrates are separated or “diced” into the individual devices called “chips” prior to picking for later processing and packaging into products.

A substrate with finished devices on the top side that has been thinned and optionally had metallization applied to the bottom side, is affixed to dicing tape by an adhesive applied to the dicing tape. The dicing tape is affixed to a dicing ring of and together with the finished devices, form a tape frame substrate. The ring supports tape around the perimeter of the tape frame substrate. After the dicing process has been completed, the dicing tape continues to support the diced chips in place where they were diced from the semiconductor substrate. However, any subsequent plasma processing of the tape frame substrate causes etching of unprotected dicing tape and any gaps between the tape frame substrate and processing chamber components, such as process kits, may lead to unwanted arcing.

Accordingly, the inventors have provided herein embodiments of improved process kits.

### SUMMARY

Embodiments of process kits for use in a substrate process chamber are provided herein. A process kit for a substrate process chamber including: a cover ring configured to extend over unprotected dicing tape of a tape frame substrate during use and having a central opening configured to expose a semiconductor wafer supported on the dicing tape during use; and a metallic shield disposed adjacent to at least a portion of a lower surface of the cover ring such that the metallic shield at least partially lines the lower surface.

In some embodiments, a substrate support for a substrate process chamber includes: a pedestal having a support surface configured to support a tape frame substrate and having one or more electrodes disposed therein; and a process kit configured cover a portion of the pedestal to define a gap between a lower surface of the process kit and the support surface sufficient to extend over and accommodate unprotected dicing tape of the tape frame substrate during use, the process kit comprising: a cover ring configured to extend over the unprotected dicing tape of the tape frame substrate during use and having a central opening configured to expose a semiconductor wafer supported on the dicing tape during use; and a metallic shield electrically connected to the pedestal and disposed adjacent to at least a portion of a lower surface of the cover ring such that the metallic shield at least partially lines the gap.

In some embodiments, a process chamber includes: a chamber body having an interior volume therein; a pedestal disposed in the interior volume and having a support surface for a tape frame substrate and one or more electrodes disposed therein; a cover ring configured to extend over unprotected dicing tape of the tape frame substrate during use and having a central opening configured to expose a semiconductor wafer supported on the dicing tape during use; and a metallic shield electrically coupled to the pedestal and disposed adjacent to at least a portion of a lower surface of the cover ring such that the metallic shield at least partially lines the lower surface.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic side view of a process chamber in accordance with at least some embodiments of the present disclosure.

FIG. 2 depicts a substrate 112 in accordance with at least some embodiments of the present disclosure.

FIG. 3 depicts a schematic cross-sectional side view of a substrate support in accordance with at least some embodiments of the present disclosure.

FIG. 4 depicts a schematic cross-sectional side view of a substrate support in accordance with at least some embodiments of the present disclosure.

FIG. 5 depicts a schematic bottom view of a process kit in accordance with at least some embodiments of the present disclosure.

FIG. 6 depicts a schematic bottom view of a process kit in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

A tape frame (TF) substrate generally includes a plurality of finished devices, dies, or chips, affixed to dicing tape. Once the dies are affixed, the TF substrate may proceed to further processing, for example, delivered to an apparatus that can pick individual dies from the dicing tape. However, any subsequent plasma processing of the TF substrate causes etching of unprotected dicing tape. Thus, a cover ring may be placed over the exposed dicing tape. However, a gap or cavity between the cover ring and the covered areas of the TF substrate may generate secondary plasma that can be ignited and cause unstable and unrepeatable plasma processing of the devices adhered to the dicing tape.

A metallic shield ring is disposed between the cover ring and the TF substrate. The metallic shield ring is electrically coupled to an RF source, for example, an RF hot pedestal of a plasma process chamber, or a separate RF power source, so that the metallic shield ring creates an equipotential region proximate the gap between the clamp and the TF substrate, thereby reducing or preventing arcing in that region.

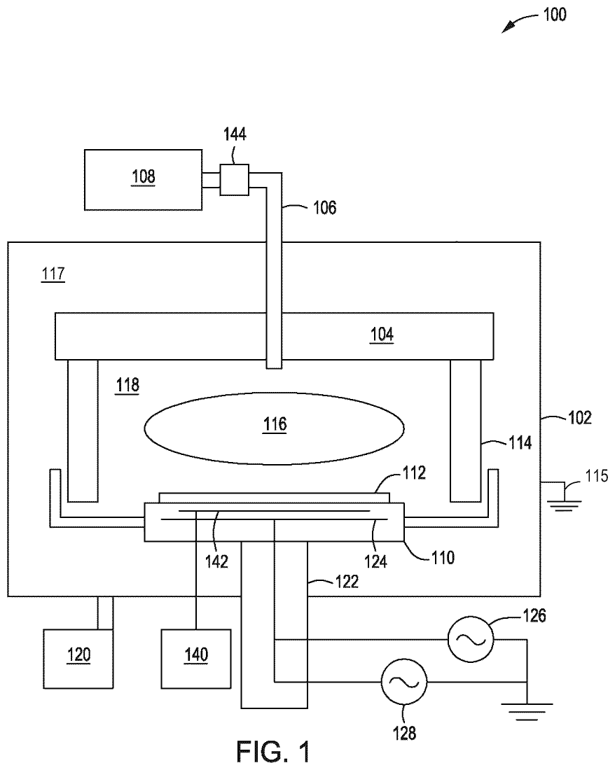

FIG. 1 is a schematic side view of a plasma process chamber 100 in accordance with at least some embodiments of the present disclosure. The plasma process chamber 100 includes a chamber body 102 defining an interior volume 117 therein. A substrate support 122 is disposed in the interior volume 117 and includes a pedestal 110 having a support surface for supporting a substrate 112, or TF substrate, to be disposed thereon. The pedestal 110 may be an electrostatic chuck (ESC) having one or more electrodes 124 disposed therein or non-chucking substrate holder (not shown). A shield 114 may be disposed in the interior volume 117 and may surround a processing volume 118. The chamber body 102 may be coupled to ground 115.

A gas supply 108 is coupled to the chamber body 102 to provide one or more process gases to the processing volume 118 via a supply conduit 106 from the gas supply 108. The one or more process gases may be provided by a showerhead 104 disposed in the interior volume 117. The process gas flow rate is controlled by a gas flow valve 144. In some embodiments, as depicted in FIG. 1, the plasma process chamber 100 is a capacitively coupled plasma chamber that forms plasma 116 in the processing volume 118 to process the substrate 112 on the pedestal 110. The plasma process chamber 100 may be a chamber configured for surface activation, etching, deposition, or the like.

Ions produced from the one or more process gases by plasma reactions are influenced by a first bias power supply 126 that are electrically connected to the one or more electrodes 124 disposed in the pedestal 110. In some embodiments, a second bias power supply 128 is electrically connected to the one or more electrodes 124. In some embodiments, the first bias power supply 126 produces RF power at a first frequency of approximately 400 kHz to approximately 15 MHz. In some embodiments, the first bias power supply 126 produces RF power at a first frequency of approximately 13.56 MHz. The first frequency allows tuning of the ion energy of the ions produced from the plasma and the process gas based on a first level of power produced by the first bias power supply 126. In some embodiments, the first power level may be greater than zero to approximately 2000 W.

In some embodiments, the second bias power supply 128 produces RF power at a second frequency of approximately 40 MHz to approximately 110 MHz. In some embodiments, the second bias power supply 128 produces RF power at a second frequency of approximately 60 MHz. The second frequency allows tuning of the ion density of the ions produced from the plasma and the process gas based on a second level of power produced by the second bias power supply 128. In some embodiments, the second power level may be greater than zero to approximately 2000 W.

As the plasma and ions interact with the substrate 112, contaminants may be formed which are removed from the plasma process chamber 100 by a pump 120. The pump 120 may also be used to maintain the process pressure within the plasma process chamber 100. In some embodiments, the process pressure may be from approximately 0.7 mTorr to approximately 20 mTorr. The plasma process chamber 100 may also have cooling and/or heating elements or channels 142 that allow temperature control of the substrate 112 during processing by a temperature controller 140. The plasma process chamber 100 may be a plasma chamber that is part of a hybrid bonding process flow and configured for processing of tape frame substrates as described in more detail below.

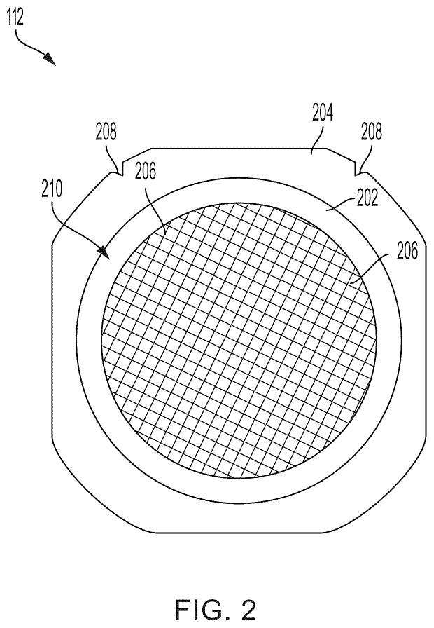

FIG. 2 depicts a substrate 112 in accordance with at least some embodiments of the present disclosure. In some embodiments, the substrate 112 is a tape frame substrate that generally comprises a layer of dicing tape 202 surrounded by a tape frame 204. In use, a plurality of chiplets 206 can be attached to the dicing tape 202. The plurality of chiplets 206 are generally formed via a singulation process that dices a semiconductor wafer 210 into the plurality of chiplets 206 or dies. In some embodiments, the tape frame 204 is made of metal, such as stainless steel. The tape frame 204 may have one or more notches 208 to facilitate alignment and handling. For a semiconductor wafer 210 having a 300 mm diameter, the tape frame 204 may have a width of about 340 mm to about 420 mm and a length of about 340 mm to about 420 mm.

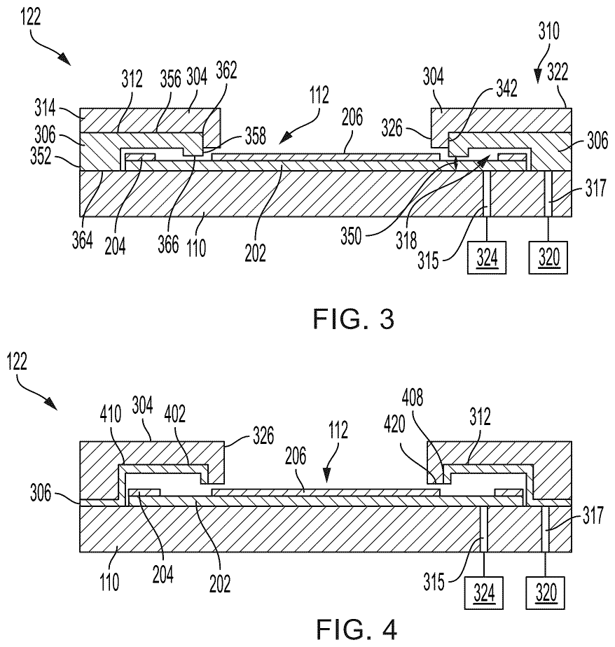

FIG. 3 depicts a schematic cross-sectional side view of a substrate support 122 in accordance with at least some embodiments of the present disclosure. The substrate 112 is disposed on the substrate support 122. During a plasma process, the dicing tape 202 may be exposed to the plasma 116 in a region between the semiconductor wafer 210 (or plurality of chiplets 206) and the tape frame 204. The exposed regions of the dicing tape 202 causes etching of the exposed or unprotected regions of the dicing tape 202, leading to wearing of the dicing tape 202 and contamination of the semiconductor wafer 210 (or plurality of chiplets 206).

The substrate support 122 includes a process kit 310 disposed on the pedestal 110. The process kit 310 includes a cover ring 304 configured to cover a portion of the pedestal 110 to define a gap 318 between a lower surface 312 of the process kit 310 and the support surface of the pedestal 110 sufficient to extend over and accommodate unprotected areas of the dicing tape 202 during use. The cover ring 304 is configured to extend over the unprotected dicing tape of the TF substrate during use and having a central opening configured to expose the semiconductor wafer 210 during use.

For example, an inner diameter of the cover ring 304 is slightly less than an outer diameter of the semiconductor wafer 210, for example, about 0.1 to about 2 mm less. In some embodiments, the cover ring 304 is made of quartz. In some embodiments, the cover ring 304 includes a body 322 and an inner lip 326 extending down from the body 322. In some embodiments, an outer surface 342 of the inner lip 326 is disposed radially outward of the semiconductor wafer 210. The gap 318 between the cover ring 304 and the substrate 112 may be prone to secondary plasma and arcing.

The process kit 310 advantageously includes a metallic shield 306 made of a conductive material and electrically connected to the pedestal 110. The cover ring 304 and the metallic shield 306 are generally sized to accommodate the substrate 112. In some embodiments, the metallic shield 306 is made of aluminum or copper. The metallic shield 306 is disposed in the gap 318 between the cover ring 304 and the substrate 112. For example, the metallic shield 306 is disposed adjacent to at least a portion of the lower surface 312 of the cover ring 304 such that the metallic shield 306 at least partially lines the gap 318. The metallic shield 306 advantageously provides an equipotential region in the gap 318, thereby substantially reducing or preventing the formation of secondary plasma or arcing in the gap 318. In some embodiments, the metallic shield 306 includes an outer portion 352, a ledge 356 extending radially inward from the outer portion 352, and a lip 358 extending downward from a radially inner edge 362 of the ledge 356. In some embodiments, the metallic shield 306 has a substantially uniform thickness.

In some embodiments, a distance 350 between the lower surface 364 of the outer portion 352 and a lower surface 366 of the lip 358 is less than about 2 mm. In some embodiments, a gap between the lip 358 of the metallic shield 306 and the pedestal 110 is between about 0.2 to about 2 mm. In some embodiments, an outer surface 314 of the cover ring 304 is substantially coplanar with an outer surface of the metallic shield 306. In inner diameter of the outer portion 352 of the metallic shield 306 may be sized to be slightly greater than an outer diameter of the substrate 112. In some embodiments, as depicted in FIG. 3, the metallic shield 306 is a separate component from the cover ring 304.

The pedestal 110 may include one or more substrate lift openings 315 for accommodating lift pins for selectively raising or lowering the substrate 112. A lift assembly 324 comprising one or more actuators is coupled to the pedestal 110 and configured to selectively raise or lower lift pins through the one or more substrate lift openings 315. The pedestal 110 may include one or more kit lift openings 317 for accommodating lift pins for selectively raising or lowering the process kit 310. A lift assembly 320 comprising one or more actuators is coupled to the pedestal 110 and configured to selectively raise or lower lift pins through the one or more kit lift openings 317.

FIG. 4 depicts a schematic cross-sectional side view of a substrate support 122 in accordance with at least some embodiments of the present disclosure. In some embodiments, as illustrated in FIG. 4, the metallic shield 306 is coupled to the cover ring 304 in a suitable manner. For example, the metallic shield 306 may be deposited, coated, affixed via an adhesive, fastened, or the like, to the cover ring 304. In some examples, the metallic shield 306 comprises a metallic coating 402 applied on a lower surface 312 of the cover ring 304. In some embodiments, the metallic coating 402 has a thickness of about 100 microns to about 500 microns. In some embodiments, the metallic coating 402 is applied to a lower surface 410 of the body 322 and a radially outer surface 408 of the inner lip 326. In some embodiments, the metallic coating 402 is applied to a lower surface of the body 322 and not to a lower surface 420 of the inner lip 326.

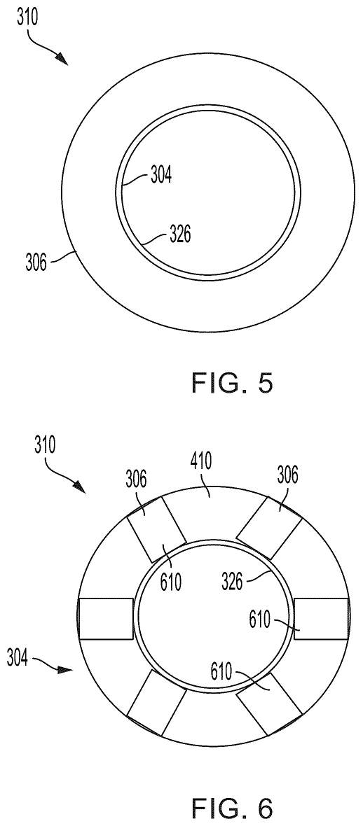

FIG. 5 depicts a schematic bottom view of a process kit 310 in accordance with at least some embodiments of the present disclosure. FIG. 6 depicts a schematic bottom view of a process kit 310 in accordance with at least some embodiments of the present disclosure. In some embodiments, as illustrated in FIG. 5, the metallic shield 306 comprises a continuous annular shield. In some embodiments, as illustrated in FIG. 6, the metallic shield 306 includes a plurality of segments 610 disposed at regular intervals about the cover ring 304 and only partially covering the lower surface 410 of the body 322 of the cover ring 304. In some embodiments, the plurality of segments 610 cover about 30 percent or more of the total surface area of the lower surface 410.

While the foregoing is directed to embodiments of the present disclosure, other and further embodiments of the disclosure may be devised without departing from the basic scope thereof.

1. A process kit for a substrate process chamber, comprising:
a cover ring configured to extend over unprotected dicing tape of a tape frame substrate during use and having a central opening configured to expose a semiconductor wafer supported on the dicing tape during use; and
a metallic shield disposed adjacent to at least a portion of a lower surface of the cover ring such that the metallic shield at least partially lines the lower surface.

2. The process kit of claim 1, wherein the metallic shield comprises a continuous annular shield.

3. The process kit of claim 1, wherein the metallic shield includes a plurality of segments disposed at regular intervals about the cover ring and partially cover a lower surface of a body of the cover ring.

4. The process kit of claim 1, wherein the cover ring is made of quartz.

5. The process kit of claim 1, wherein the metallic shield includes an outer portion, a ledge extending radially inward from the outer portion, and a lip extending downward from a radially inner edge of the ledge.

6. The process kit of claim 5, wherein a distance between a lower surface of the outer portion and a lower surface of the lip is less than about 2 mm.

7. The process kit of claim 1, wherein the metallic shield comprises a metallic coating on a lower surface of the cover ring.

8. The process kit of claim 7, wherein the metallic coating has a thickness of about 100 microns to about 500 microns.

9. A substrate support for a substrate process chamber, comprising:
a pedestal having a support surface configured to support a tape frame substrate and having one or more electrodes disposed therein; and
a process kit configured cover a portion of the pedestal to define a gap between a lower surface of the process kit and the support surface sufficient to extend over and accommodate unprotected dicing tape of the tape frame substrate during use, the process kit comprising:
a cover ring configured to extend over the unprotected dicing tape of the tape frame substrate during use and having a central opening configured to expose a semiconductor wafer supported on the dicing tape during use; and
a metallic shield electrically connected to the pedestal and disposed adjacent to at least a portion of a lower surface of the cover ring such that the metallic shield at least partially lines the gap.

10. The substrate support of claim 9, wherein the metallic shield comprises a continuous annular shield.

11. The substrate support of claim 9, wherein the metallic shield includes a plurality of segments disposed at regular intervals about the cover ring and partially cover a lower surface of a body of the cover ring.

12. The substrate support of claim 9, wherein the cover ring includes a body and an inner lip extending down from the body.

13. The substrate support of claim 9, wherein the metallic shield comprises a metallic coating on a lower surface of the cover ring.

14. The substrate support of claim 9, wherein an outer surface of the cover ring is substantially coplanar with an outer surface of the metallic shield.

15. A process chamber, comprising:
a chamber body having an interior volume therein;
a pedestal disposed in the interior volume and having a support surface for a tape frame substrate and one or more electrodes disposed therein;
a cover ring configured to extend over unprotected dicing tape of the tape frame substrate during use and having a central opening configured to expose a semiconductor wafer supported on the dicing tape during use; and
a metallic shield electrically coupled to the pedestal and disposed adjacent to at least a portion of a lower surface of the cover ring such that the metallic shield at least partially lines the lower surface.

16. The process chamber of claim 15, wherein the metallic shield comprises a metallic coating on a lower surface of the cover ring.

17. The process chamber of claim 15, wherein the metallic shield is separate from the cover ring.

18. The process chamber of claim 15, further comprising an RF power source coupled to the one or more electrodes in the pedestal.

19. The process chamber of claim 15, wherein the metallic shield is made of aluminum or copper.

20. The process chamber of claim 15, wherein the metallic shield includes an outer portion, a ledge extending radially inward from the outer portion, and a lip extending downward from a radially inner edge of the ledge, and wherein a gap between the lip and the pedestal is between about 0.2 to about 2 mm.
